(19) United States
(12) Patent Application Publication
(10) Pub. No.: US 2025/0385126 A1
(43) Pub. Date: Dec. 18, 2025

(54) INTERCONNECT STRUCTURE WITH RELAXED VIA-CORNER SLOPE

(71) Applicant: NXP USA, INC., AUSTIN, TX (US)

(72) Inventors: Mehul D. Shroff, Austin, TX (US); Douglas Michael Reber, Austin, TX (US); Ertugrul Demircan, Eugene, OR (US)

(21) Appl. No.: 18/745,206

(22) Filed: Jun. 17, 2024

(51) Int. Cl. H01L 21/768

(52) U.S. Cl. CPC H01L 21/76807; H01L 21/7684; H01L 21/76829; H01L 21/76843; H01L 21/76877

(57) ABSTRACT

Described herein is a process for forming a multi-level interconnect structure formed in a via interlayer dielectric (ILD) layer and in an interconnect interlayer dielectric layer where an etch-stop layer is located between the interconnect ILD layer and the via ILD layer. At least a top portion of the etch-stop layer immediately adjacent to an opening in the etch-stop layer aligned with an opening in the via ILD layer is removed before the formation of the multi-level interconnect structure.

### BACKGROUND OF THE INVENTION

### FIELD OF THE INVENTION

This invention relates in general to a semiconductor die with multi-level interconnect structures.

### DESCRIPTION OF THE RELATED ART

Some semiconductor dice utilize multi-level interconnect structures in the back-end layer (e.g., metal layers and intervening via interconnect layers) of a semiconductor die. A multi-level interconnect structure is a conductive structure that is located in two or more back-end layers.

### BRIEF DESCRIPTION OF THE DRAWINGS

The present invention may be better understood, and its numerous objects, features, and advantages made apparent to those skilled in the art by referencing the accompanying drawings.

FIG. 1 is a partial cutaway side view of a prior art wafer during a stage of manufacture.

FIG. 2 is a partial cutaway side view of a prior art wafer during a stage of manufacture.

FIG. 3 is a partial cutaway side view of a wafer during a stage in the manufacture of a semiconductor die according to one embodiment of the present invention.

FIGS. 4-10 are partial cutaway side views of a wafer during various stages in the manufacture of a semiconductor die according to one embodiment of the present invention.

FIGS. 11-13 are partial cutaway side views of a wafer during various stages in the manufacture of a semiconductor die according to one embodiment of the present invention.

FIG. 14 is a partial cutaway side view of a wafer during a stage in the manufacture of a semiconductor die according to one embodiment of the present invention.

FIG. 15 is a partial cutaway side view of a wafer during a stage in the manufacture of a semiconductor die according to one embodiment of the present invention.

The use of the same reference symbols in different drawings indicates identical items unless otherwise noted. The figures are not necessarily drawn to scale.

### DETAILED DESCRIPTION

The following sets forth a detailed description of at least one mode for carrying out the invention. The description is intended to be illustrative of the invention and should not be taken to be limiting.

Described herein is a process for forming a multi-level interconnect structure formed in a via interlayer dielectric (ILD) layer and in an interconnect interlayer dielectric layer where an etch-stop layer is located between the interconnect ILD layer and the via ILD layer. At least a top portion of the etch-stop layer immediately adjacent to an opening in the etch-stop layer aligned with an opening in the via ILD layer is removed before the formation of the multi-level interconnect structure.

In some embodiments, removal of at least a top portion of the etch-stop layer immediately adjacent to the opening may provide for an improved process where a transition portion between the via portion of the multi-level interconnect and the interconnect portion of the multi-level interconnect is at a more relaxed angle (greater than 90 degrees) such that the barrier and seed layers of the multi-level interconnect structure can be fully formed along the sidewalls of the via ILD layer near the transition area without gaps or voids. Accordingly, the interconnect material does not diffuse in the ILD layer. Furthermore, with a better formation of the barrier and seed layers, voids in the interconnect material are less likely to form at the transition area, which may provide for a better electromigration performance.

FIG. 1 is a partial cutaway side view of a prior art wafer 101 that includes a multi-level interconnect structure 111 located in an interlayer dielectric layer 105 of a back-end layer of the wafer. Interconnect structure 111 includes an interconnect portion 113 and a via portion 115. Interconnect structure 111 includes a conductive barrier layer 117 on the lateral and bottom sides of the interconnect structure. The bottom side of via portion 115 is in electrical contact with another multi-level conductive structure 103, located in a lower ILD layer 108.

In FIG. 1, via portion 115 is considered to have a relatively high aspect ratio (i.e., having relatively vertical sidewalls). Vias with a relatively high aspect ratio may have a transition between the interconnect portion 113 and the via portion 115 close to 90 degrees (e.g., at location 119 in FIG. 1). One issue with such a “sharp” transition is that a portion of the sidewall of ILD layer 105 corresponding to the via portion (e.g., at location 119) may be “shadowed” during the formation of barrier layer 117 such that less than a minimum amount of barrier layer material is deposited on the sidewall of ILD layer 105 at that location. With poor barrier layer coverage, the conductive non-barrier material (e.g., copper, gold) of interconnect structure 111 may diffuse into ILD layer 105 at that location. Furthermore, the sharp transition may reduce the amount of a non-barrier material seed layer (not shown in FIG. 1) deposited on the sidewall of ILD layer 105 at that location. Accordingly, voids in the interconnect material may occur, which may lead to electromigration issues for a signal carried on the via.

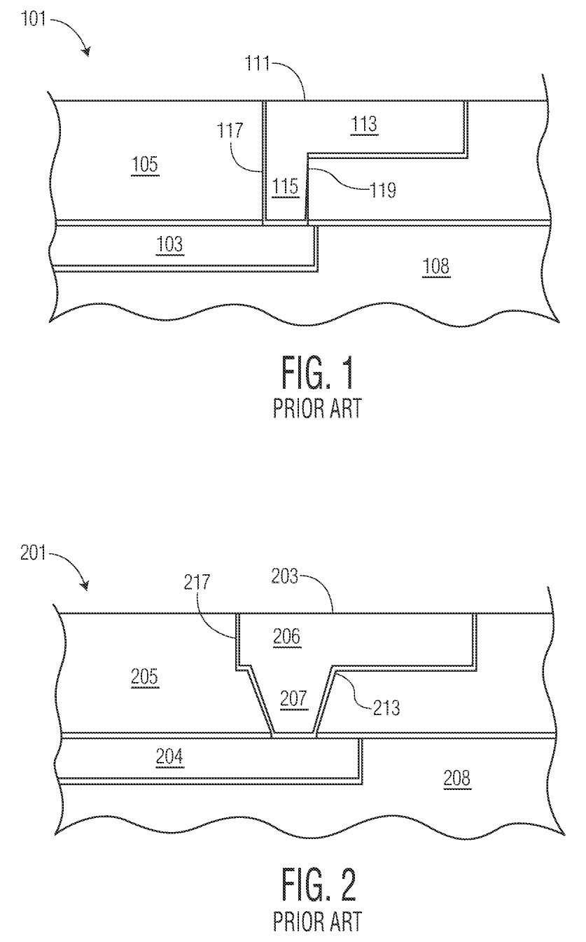

FIG. 2 is a partial cutaway side view of a prior-art wafer 201 that includes multi-level interconnect structure 203 located in an interlayer dielectric layer 205 of a back-end layer of wafer 201. Interconnect structure 203 includes an interconnect portion 206 and a via portion 207. Interconnect structure 203 includes a conductive barrier layer 217 on the lateral and bottom sides of the interconnect structure. The bottom side of via portion 207 is in electrical contact with another multi-level conductive structure 204 located in a lower level ILD layer 208.

Via portion 207 is different than via portion 115 of FIG. 1 in that its sidewall has a lower aspect ratio, as shown by the sloped sidewall in FIG. 2. Accordingly, the transition between the bottom of interconnect portion 206 and the sidewall of via portion 207 is significantly greater than 90 degrees and is more relaxed than with interconnect structure 111 in FIG. 1. Because of the higher transition angle and significantly sloped via sidewall, the material of barrier layer 217 is adequately formed on the sidewall of ILD layer 205 at location 213 to prevent copper from migrating to ILD layer 205. However, providing lower aspect ratio vias requires a greater area for the interconnect portion of an interconnect structure thereby increasing the area of the interconnect structure in an ILD layer. Accordingly, fewer interconnect structures can be located within a back-end layer of an integrated circuit.

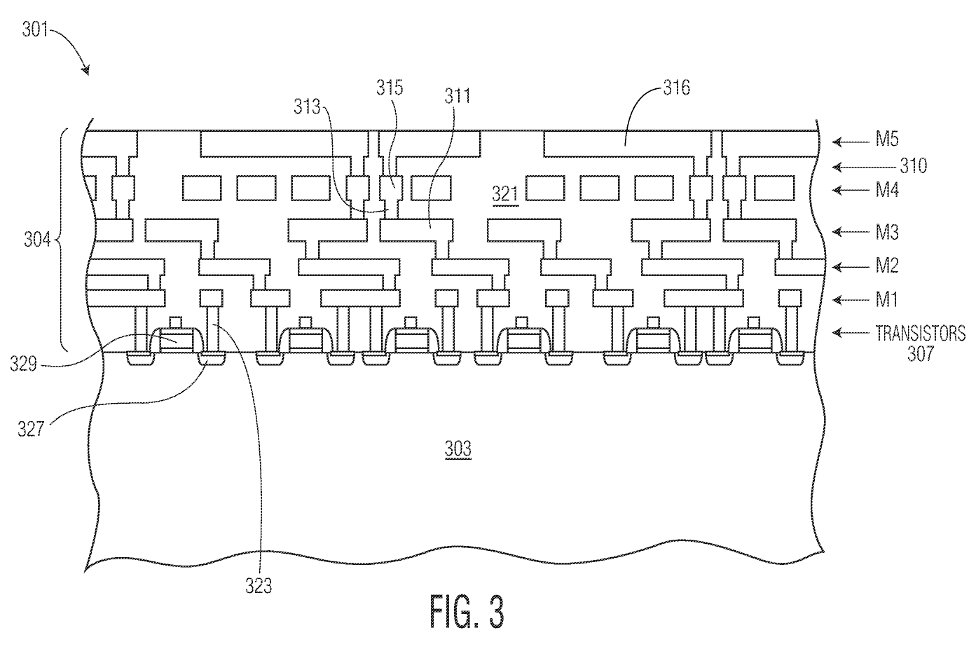

FIG. 3 is a cutaway side view of a wafer according to one embodiment of the present invention. Wafer 301 includes a substrate 303 that in one embodiment is made of monocrystalline silicon, but may be made of other types of semiconductor material (e.g., silicon germanium, silicon carbon, gallium nitride, or other III-V semiconductor material) in other embodiments. In the embodiment shown, substrate 303 has a bulk semiconductor configuration. In other embodiments, substrate 303 may have other configurations such an SOI (semiconductor-on-insulator) configuration. Substrate 303 may be formed from a slice of a semiconductor ingot. In some embodiments, substrate 303 may include epitaxial layers grown on the ingot slice. Not shown in FIG. 3 are dielectric materials in substrate 303 (e.g., such as isolation structures and buried oxide layers).

During wafer processing, semiconductor devices such as transistors, resistors, and diodes may be formed in substrate 303 by selectively doping regions of substrate 303 with conductivity-altering dopants (conductivity dopants) such as N-type dopants (arsenic and phosphorus) and P-type dopants (boron). In the example of FIG. 3, multiple transistors 307 are formed in substrate 303. In the embodiment shown, the transistors are field-effect transistors with the source and drain regions (e.g., region 327) located in substrate 303 and the gates (e.g., gate 329) located on a gate dielectric above substrate 303. However, a wafer may include other types of semiconductor devices such as other types of transistors or diodes in other embodiments. In some embodiments, the semiconductor devices may be located in semiconductor fins of substrate 303.

Wafer 301 includes a back-end layer 304 located over substrate 303. Back-end layer 304 includes one or more metal layers with layers M1-M5 being shown in FIG. 3. As used herein, a “metal layer” of a back-end layer is a layer that includes interconnects (e.g., 311, 315, 316) laterally separated by an interconnect ILD layer of dielectric material where at least some of the interconnects of the metal layer provide both a horizontal and a vertical component for a conductive signal path or bias path between semiconductor device terminals of the semiconductor die and/or between at least one semiconductor device terminal and at least one external die terminal (e.g., bond pad, bond post – not shown in FIG. 3) of the die. The interconnects are made of a type of conductive material (e.g., copper, gold, aluminum) and may include conductive barrier material (e.g., tantalum, titanium, tantalum nitride, titanium nitride).

Back-end layer 304 includes via layers (310) located in between the metal layers. The via layers include conductive vias (e.g., 313) for providing a vertical conductive path between an interconnect (e.g., 311) of one metal layer (e.g., M3) and an interconnect (e.g., 315) of another metal layer (e.g., M4). The conductive vias are made of the same type of material as the interconnects and are contiguous with the interconnects of the immediately above metal layer to implement a multi-layer interconnect structure. The via layers also include a via ILD layer of dielectric material (e.g., oxide) that laterally separates the vias in each via layer. Back-end layer 304 also includes contacts (e.g., contact 323) for providing a conductive path from terminals of the semiconductor devices (e.g., region 327) to the interconnects of metal layer M1.

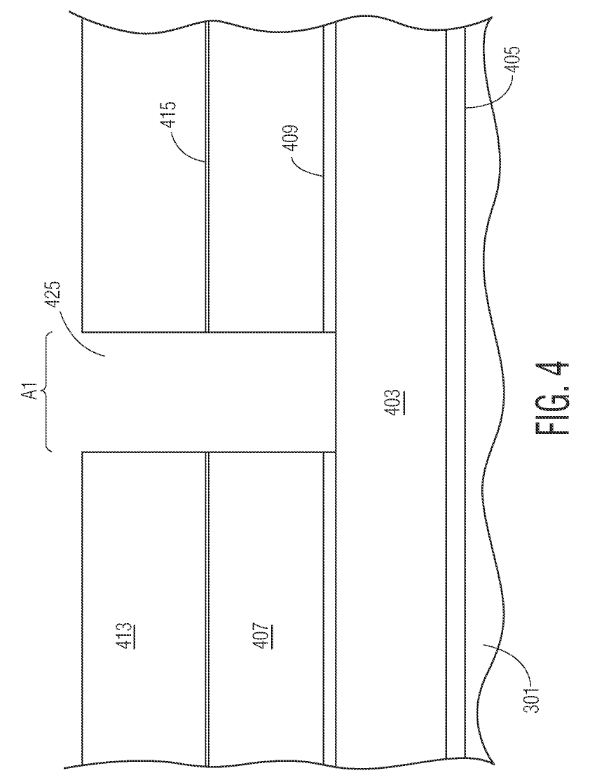

In FIG. 3, the dielectric material 321 of the ILD layers of the via layers (“via ILD layers”) and the ILD layers of the metal layers (also referred to as “interconnect ILD layers”) are shown as a continuous material throughout back-end layer 304. However, dielectric material 321 is formed in layers as part of the formation of the metal layers and the intervening via layers. As will be shown in FIG. 4, an etch-stop layer (415) is located at the boundary of the top of each via ILD layer (407) and the bottom of an interconnect ILD layer (413).

As will be subsequently described, the conductive structures of metal layers M2-M5 and the intervening via layers (310) are formed by a dual-damascene process where the interconnects of a metal layer and the conductive vias of the underlying via layer are contiguous and formed during the same process steps.

FIGS. 4-11 are partial cutaway side views of wafer 301 at various stages in the formation of a multilayer interconnect structure located in back-end layer 304. Similar interconnect structures may be formed in various locations of wafer 301 and at different metal and via layers of back-end layer 304.

In FIG. 4, a dielectric barrier layer 409 is formed on a preceding metal layer that includes an interconnect portion 403 of a multi-level interconnect structure where the via portion of the interconnect structure is not shown in the view of FIG. 4. In one embodiment, dielectric barrier layer 409 is made of Si3N4, SiO2, SiOC, SiOF, TEOS, F-TEOS, or other suitable dielectric materials. Interconnect portion 403 includes a barrier layer 405 shown at the bottom of interconnect portion 403.

After the formation of dielectric barrier layer 409, a via ILD layer 407 is formed over wafer 101. A dielectric etch-stop layer 415 is formed over via ILD layer 407, followed by interconnect ILD layer 413 being formed over etch-stop layer 415. In some embodiments, layers 407 and 415 are made of an oxide formed by a tetraethyl orthosilicate (TEOS) process, but may be made of other materials in other embodiments. In some embodiments, etch-stop layer 415 is made of nitride and has a thickness in the range of 50-450 angstroms, but may be made of other materials and be of other thicknesses in other embodiments. In some embodiments, layer 415 is made of a material that is etch-selectable with respect to the material of layers 413 and 407. In some embodiments, layers 407 and 413 are made of different materials.

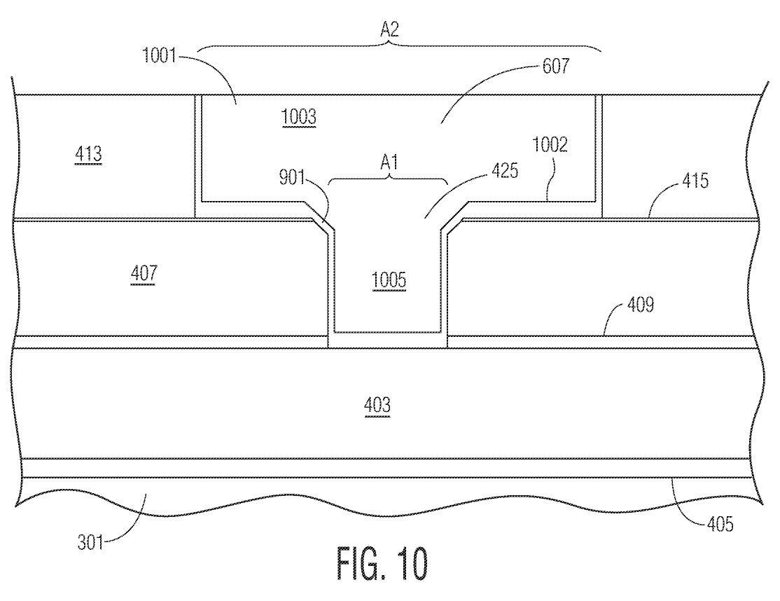

After the formation of layer 413, an opening 425 is formed in layers 413, 415, 407, and 409 by a photolithographic process where a photoresist material (not shown) is formed over wafer 301 and selectively exposed to UV radiation to form a mask structure (not shown) that includes an opening for etching layers 413, 415, 407, and 409 to expose interconnect portion 403. In the embodiment shown, opening 425 has an area of A1. Area A1 is sized to define the cross sectional area of a subsequently formed via portion 1005 of a multi-level interconnect structure 1001 (see FIG. 10). In some embodiments, the area of opening 425 is circular, but may have other shapes in other embodiments. Each of layers 413, 415, 407 and 409 is anisotropically etched with an etch chemistry that is etch-selective with respect to the material being etched. Afterwards, the mask is removed.

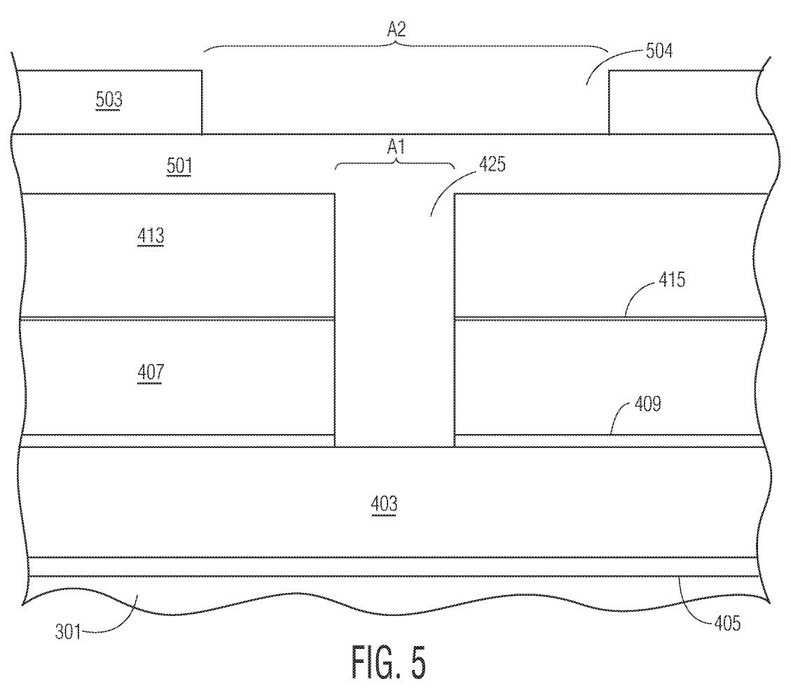

FIG. 5 is a partial cutaway side view of wafer 301 after the stage of FIG. 4. As shown in FIG. 5, a sacrificial filler 501 is formed over wafer 301, where filler 501 is planarized after formation. The material of filler 501 fills opening 425 and covers wafer 301. In some embodiments, the material of filler 501 is etch-selectable with respect to the materials of layer 413, 415, 407, and 409. In some embodiments, filler 501 is made of amorphous carbon and is deposited by chemical vapor deposition, but may be made of materials and/or deposited by other methods in other embodiments.

After the formation of filler 501 and the planarization of wafer 301, a photoresist mask 503 is formed over wafer 301 by a photolithographic process. Mask 503 has an opening 504 with an area (A2) that will define the cross-sectional area of a subsequently formed interconnect portion 1003 of a multi-level interconnect structure 1001 (see FIG. 10).

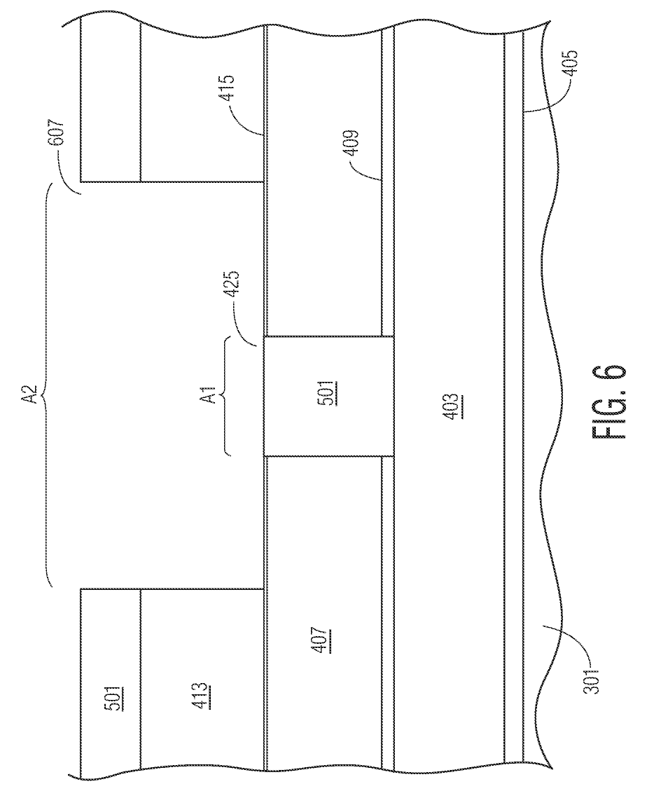

FIG. 6 is a partial cutaway side view of wafer 301 after the stage of FIG. 5. As shown in FIG. 6, the opening 504 in mask 503 was used to define an opening 607 in filler 501 and layer 413 so as to expose etch-stop layer 415. In one embodiment, filler 501 and layer 413 are anisotropically etched with an etch chemistry that is etch-selective with respect to the materials of both filler 501 and layer 413 and is etch-selective with respect to the material of layer 415. In some embodiments, the etching of filler 501 is performed by a timed etch.

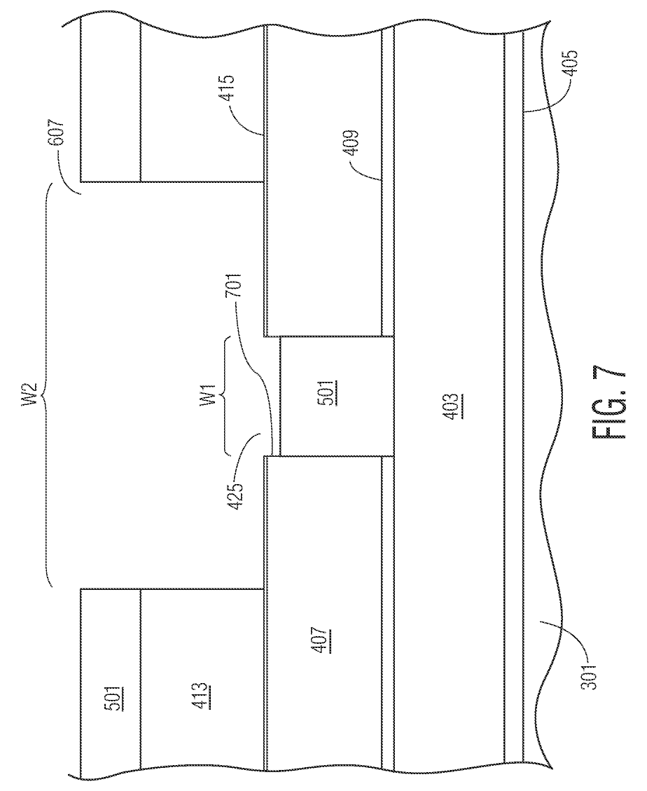

FIG. 7 is a partial cutaway side view of wafer 301 after the stage of FIG. 6. In FIG. 7, a portion of filler 501 is removed with a timed etch to expose a top portion 701 of the side wall of layer 407 in opening 425. In one embodiment, portion 701 has a depth in the range of 50-150 angstroms, but may have other depths in other embodiments. In some embodiments, the stage of FIG. 7 may be a result of the timed etch of filler 501 to form opening 607 as discussed above.

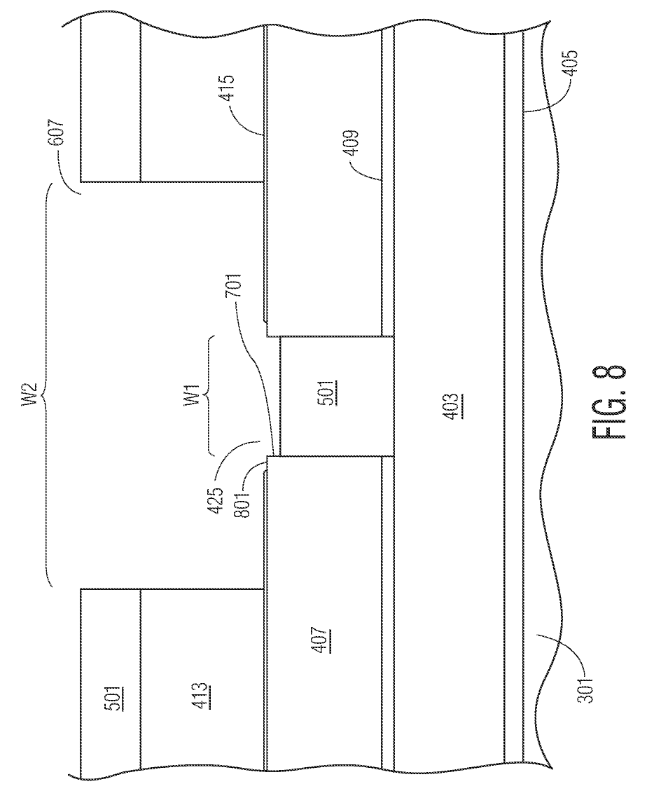

FIG. 8 is a partial cutaway side view of wafer 301 after the stage of FIG. 7. In FIG. 8, a portion of etch-stop layer 415 immediately adjacent to opening 425 is removed to expose a top portion 801 of layer 407. In some embodiments, the portion of etch-stop layer 415 is removed with a timed, isotropic etch that is selective to the material of layers 407 and 413 (oxide) and the material of filler 501 (carbon), and selective with respect to the material etch-stop layer 415 (e.g., nitride). In some embodiments, the isotropic etch removes approximately 25-75 angstroms laterally of etch-stop layer 415 from the edge of opening 425, but a different lateral amount of etch-stop layer 415 may be removed in other embodiments. In other embodiments, a directional plasma ion etch may be used to remove the portion of etch-stop layer 415 by etching in a direction having a dominant lateral component with respect to the vertical component. However, the portion of etch-stop layer 415 may be removed by other methods in other embodiments. In some embodiments, the portion of etch-stop layer 415 would be removed before etching filler 501 to expose portion 701 (as described with respect to FIG. 7).

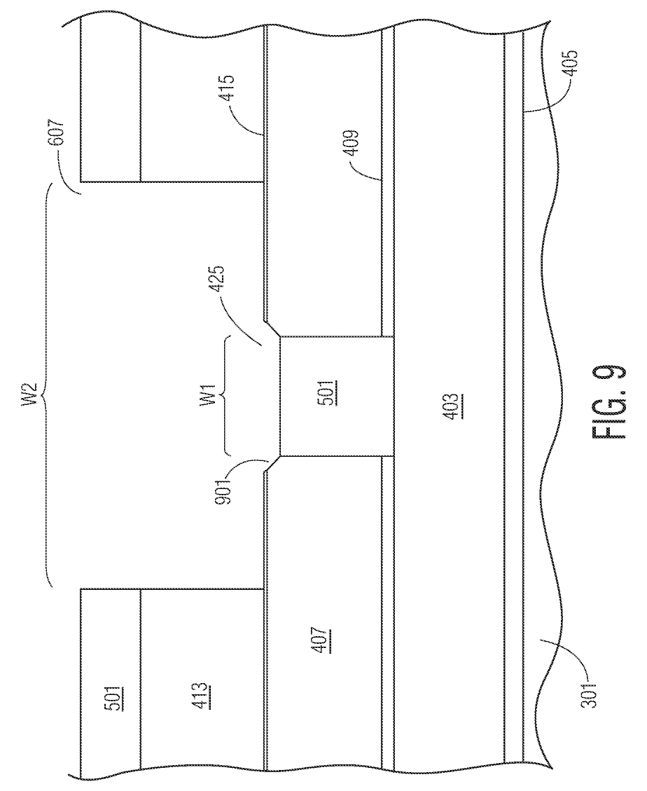

FIG. 9 is a partial cutaway side view of wafer 301 after the stage of FIG. 8. As shown in FIG. 9, a portion of the corner of the sidewall of layer 407 in opening 425 at location 901 is removed. In one embodiment, the portion at location 901 is removed with a short isotropic etch with an etch chemistry that is selective to the material of the etch-stop layer 415 and to the material of filler 501 and selective with respect to the material of layer 407. In other embodiments, the corner portion may be removed with an angled plasma-ion etch (e.g., with argon ions). In still other embodiments, the corner portion may be removed with an anisotropic etch where the material of layer 407 is etched along boundary lines at an approximately 45 degree angle.

FIG. 10 is a partial cutaway side view of wafer 301 after the stage of FIG. 9. As shown in FIG. 10, filler 501 has been removed from wafer 301 (by an etch selective with respect to the material of filler 501). Afterwards, a layer 1002 of conductive barrier layer material (e.g., tantalum, titanium, tantalum nitride or titanium nitride or other barrier layer material) is deposited on wafer 301 including in openings 607 and 425. In some embodiments, layer 1002 is deposited by an atomic layer deposition process and has thickness in the range of 50-200 Angstroms, but may be deposited by other methods such as sputtering or seedless plating, and/or be of other thicknesses in other embodiments.

As shown in FIG. 10, with the top corner of the side wall of layer 417 in opening 425 being removed at location 901, the transition from the top surface of etch-stop layer 415 opening 607 to the sidewall of layer 407 in opening 425 is more relaxed than in the stage of FIG. 8. Accordingly, the side wall of layer 407 in opening 425 is not “shadowed’ by the corner of the opening such that an adequate amount of barrier layer material can be deposited on the sidewall of layer 407 in opening 425.

Afterwards, a layer of interconnect material (e.g., copper, gold) is formed on wafer 101 to fill openings 425 and 607. In some embodiments, a seed layer of the interconnect material (e.g., copper) is deposited on wafer 301 by sputtering, atomic layer deposition, seedless plating, or other methods. Afterwards, additional conductive material is deposited on wafer 301 using a plating process to fill openings 425 and 601. In some embodiments, the additional conductive material is copper and is formed by a plating process using the seed layer as a cathode plating layer. However, interconnect structure 1001 may be made by other processes and/or be made of other types of conductive materials in other embodiments. Having a more relaxed transition from the top surface of etch-stop layer 415 to the sidewall of layer 407 may provide for an adequate amount of seed layer material being deposited at the sidewall of the barrier layer 407 in opening 425.

Afterwards, wafer 301 is planarized to remove the portions of the barrier layer and other conductive material (e.g., copper, gold) located over layer 413 to form a multi-level interconnect structure 1001. Structure 1001 includes an interconnect portion 1003 that is located in opening 607 above etch-stop layer 415 in a metal layer and a via portion 1005 that is located in opening 425 of layer 407 in a via layer. Interconnect structure 1001 may be formed by different material and/or by different processes in other embodiments.

After the stage of manufacture shown in FIG. 10, subsequent processes may be performed on wafer 101. For example, additional metal layers and via layers may be formed over layer 413. After the formation of the final metal layer of back-end layer 104, die terminals (e.g., bumps, pads, pillars – not shown) are formed over the final metal layer where each die terminal is electrically connected to an interconnect structure on the final metal layer. Afterwards, wafer 101 is singulated into multiple semiconductor dice, where each die includes multiple multi-level interconnect structures similar to interconnect structure 1001 at multiple layers of the die. The dice are then protected in semiconductor packages that can be implemented in electronic systems such as e.g., RF communications systems, motor controllers, automotive electronics systems, computers, industrial equipment, appliances, and cellular phones.

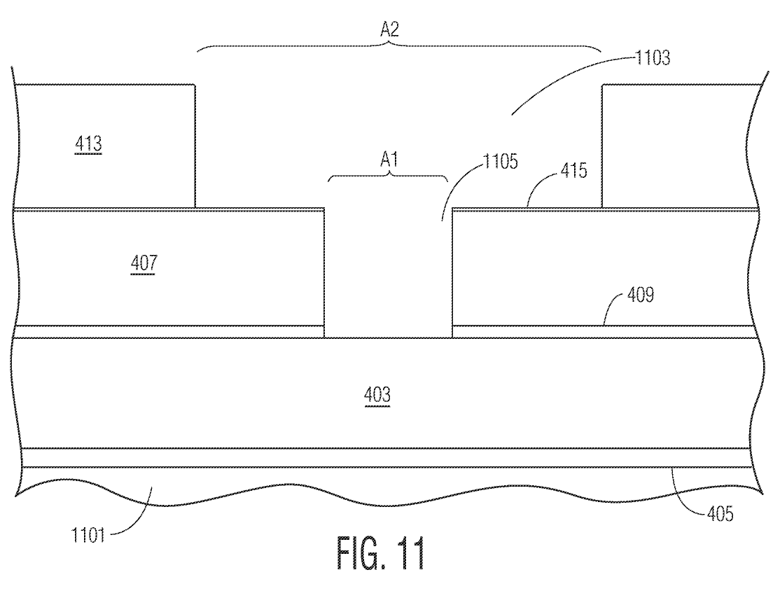

FIG. 11 is a partial cutaway side view of a wafer 1101 according to another embodiment of the invention. Items with the same reference numbers as previous figures are similar. In the embodiment of FIG. 11, wafer 1101 includes an opening 1105 in layers 409, 407, and 415 of a first area (A1) and an opening 1103 in layer 413 of a second area (A2).

In some embodiments, openings 1103 and 1105 may be formed by forming two masks (not shown) over an unpatterned layer 413 wherein a top mask has an opening the size of area A1 and the second mask has an opening the size of area A2. In some embodiments, the first mask is used to etch layers 413 and 415, to form openings in those layers at the location of area A1 by an anisotropic etch with appropriate etch chemistries to expose the top surface of layer 407. Afterwards, layers 413 and 407 are anisotropically etched with an etchant that is selective to the material of etch-stop layer 415 to form opening 1103 in layer 413 and opening 1105 in layer 407. Layer 409 is then isotopically etched to form an opening in layer 409 to expose portion 403. However, openings 1103 and 1105 may be formed by other methods in other embodiments. For example, opening 1103 in layer 413 may be formed first, followed by the formation of opening 1105 in layers 415, 407, and 409. In some embodiments, a sacrificial filler may be used (similar to filler 501).

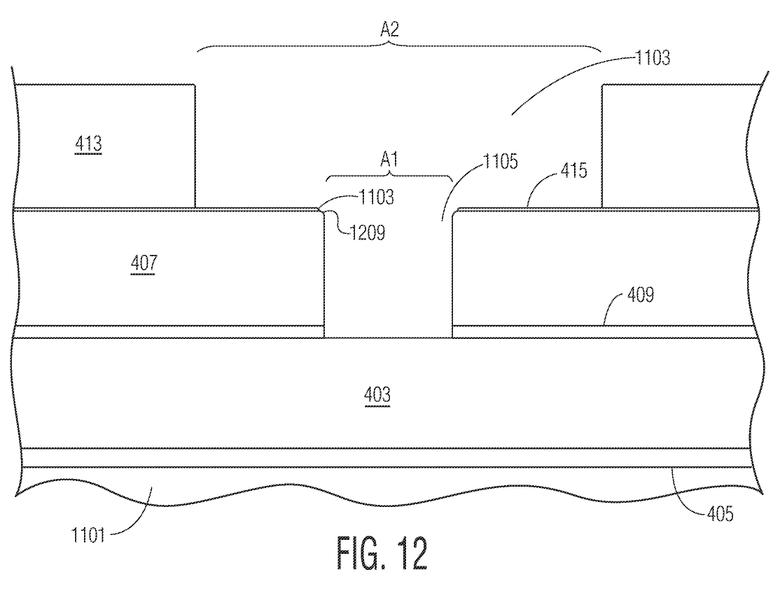

FIG. 12 is a partial cutaway side view of wafer 1101 after the stage of FIG. 11. As shown in FIG. 12, a portion of etch-stop layer 415 immediately adjacent opening 1105 is removed by an isotropic etch that is selective to the material of layers 413, 407, and 409, and portion 403 and is selective with respect to the material of layer 415, but in other embodiments, may be removed with an angled plasma ion etch. See the description of FIG. 8 above. After layer 415 has been etched, wafer 1101 may be subject to a very short isotropic etch with an etchant that is selective with respect to the material of layer 407 to round the exposed top corner 1209 of layer 407 in opening 1105.

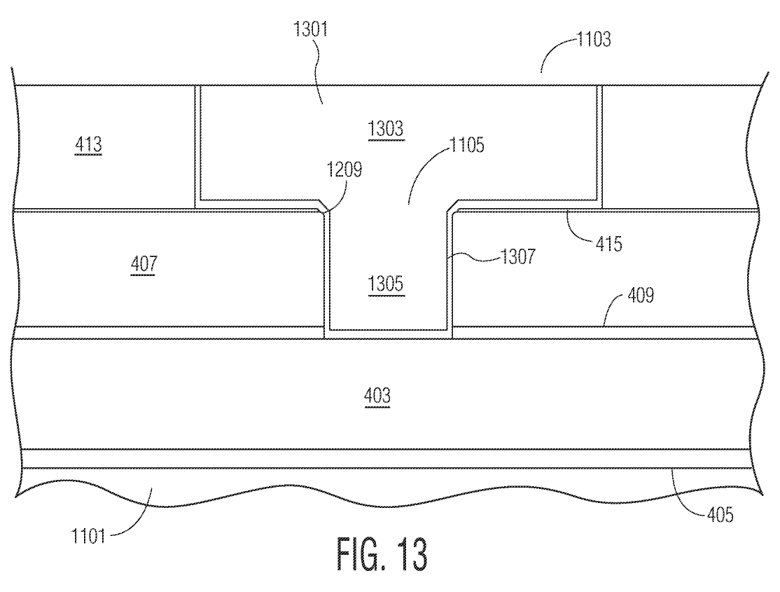

FIG. 13 is a partial cutaway side view of wafer 1101 after the stage of FIG. 12 where a multi-level interconnect structure 1301 (similar to interconnect structure 1001 of FIG. 10) is formed in openings 1103 and 1105. Structure 1301 includes an interconnect portion 1303 and a via portion 1305. Because of the etch-back of layer 415 and because corner 1209 has been rounded, the sharpness of the transition of the horizontal top surface of etch-stop layer 415 in opening 1103 to the vertical sidewall of layer 407 in opening 1105 is reduced. Accordingly, the vertical sidewall of layer 407 is not shadowed such that a sufficient amount of barrier layer material of barrier layer 1307 is deposited on the sidewall of layer 407 in opening 1105.

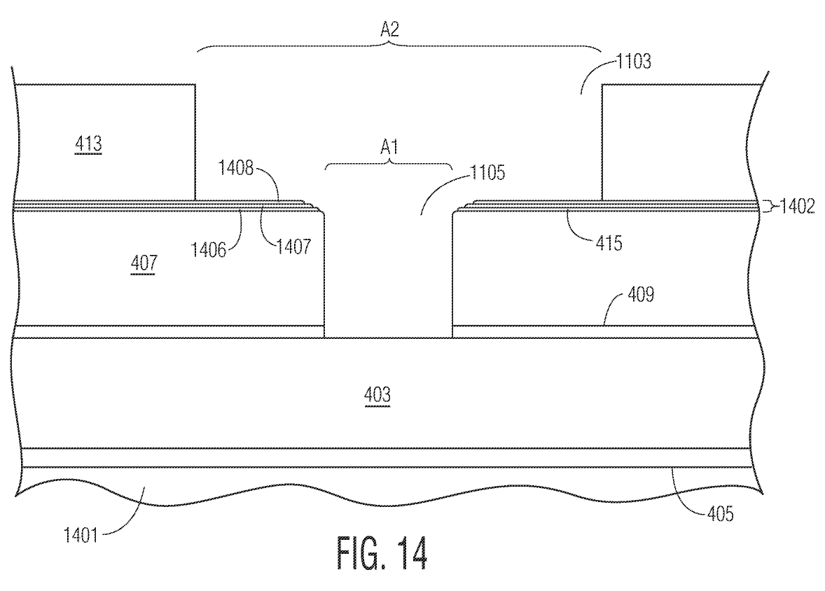

FIG. 14 is partial cutaway side view of a wafer 1401 according to another embodiment of the invention. Items with the same reference numbers as previous figures are similar. In the embodiment of FIG. 14, etch-stop layer 1402 includes sublayers 1406-1408 located between layers 413 and 407. In one embodiment, sublayers 1406-1408 are each made of a material (e.g., Si3N4, SiON, SiO2, TEOS, F-TEOS) that is etch-selectable from the materials of the other sublayers. In other embodiments, sublayers 1406 and 1408 would be made of the same material and would be etch-selectable from the material of sublayer 1407. In some embodiments, each of sublayers 1406-1408 would have a thickness in the range of 50-150 Angstroms, but may be of other thicknesses in other embodiments.

As shown in FIG. 14, each of sublayers 1406-1408 is etched back from the edge of opening 1105 with the top sublayer 1408 being etched back the furthest, followed by sublayer 1407, and then sublayer 1406. Accordingly, the transition from the top horizontal surface of sublayer 1408 in opening 1103 to the vertical sidewalls of layer 407 in opening 1105 is less abrupt than if there were a sharp 90 degree transition. Accordingly, a conductive barrier layer (not shown in FIG. 14 but similar to barrier layer 1307) for a subsequently formed multi-level interconnect structure (similar to structure 1301 of FIG. 13) will have adequate coverage on the sidewall of layer 407 in opening 1105. In some embodiments, a short isotropic etch may be performed to round the top corner of layer 407 in opening 1105. In other embodiments, etch-stop layer 1402 may have a different number of sublayers than what is shown in FIG. 14 (e.g., two or greater than three sublayers). In other embodiments, etch-stop layer 415 of the embodiment of FIGS. 4-10 may also be a multilayer etch-stop layer where the sublayers are etched back from opening 425 at different distances.

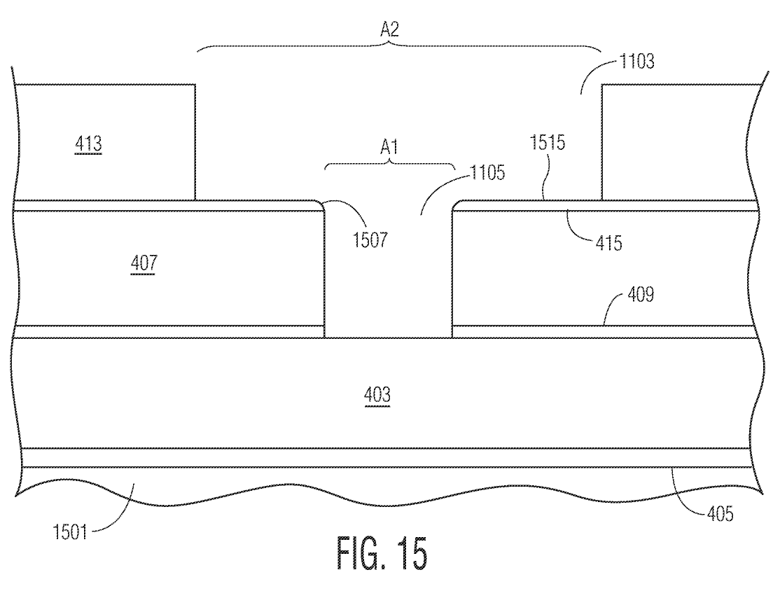

FIG. 15 is partial cutaway side view of a wafer 1401 according to another embodiment of the invention. Items with the same reference numbers as previous figures are similar. With the embodiment of FIG. 15, the top portion of etch-stop layer 1515 immediately adjacent to opening 1105 is etched to provide a sloped edge 1507 to layer 1515 to reduce the sharpness of the transition from the horizontal top surface of etch-stop layer 1515 to the vertical side walls of layer 407 in opening 1103. In some embodiments, the etching process has a relatively dominant horizontal component (e.g., as with an angled plasma ion etch). However, layer 1515 may be etched by other processes in other embodiments. In some embodiments, etch-stop layer 1515 is relatively thicker (e.g., 200-600 A) than etch-stop layer 415 (e.g., 50-450 A). After the stage of FIG. 15, a multi-level interconnect structure similar to structures 1001 or 1301 is formed in openings 1103 and 1105.

Described herein are methods for making a multi-level interconnect structure by etching at least a top portion of an etch-stop layer immediately laterally adjacent to the location of an opening in a via ILD layer. The methods may provide for a decreased sharpness of the transition of a bottom horizontal component of the interconnect structure to a relatively vertical side wall of a via component in the opening of the via ILD layer. In some of these embodiments, reducing the sharpness of this transition reduces the shadowing effect of a corner area of the transition during the deposition of a barrier layer of the multi-level interconnect, thereby providing for an adequate, continuous coating of barrier layer material that prevents diffusion of other interconnect materials into the dielectric layers. In addition, in some embodiments that utilize a seed layer for interconnect formation, a reduction in sharpness of the transition of the multi-level interconnect structure may also provide for an adequate, continuous coating of a seed layer on the barrier layer material that may provide for a more effective electroplating process. Furthermore, in some embodiments, a reduction in sharpness of the transition of the multi-level interconnect layer may allow for vias with a higher aspect ratio to be used, thereby reducing the amount of back-end layer area needed for a multi-level interconnect structure.

As disclosed herein, a first structure is “directly over” a second structure if the first structure is located over the second structure in a line having a direction that is perpendicular with a generally planar major side of the wafer or substate. For example, in FIG. 10, layer 413 is located directly over layer 407. Layer 413 is not directly over portion 1005. As disclosed herein, a first structure is “directly beneath” or “directly under” a second structure if the first structure is located beneath the second structure in a line having a direction that is perpendicular with a generally planar major side of the wafer or substrate. For example, in FIG. 10, portion 1005 is directly beneath portion 1003. Portion 1005 is not directly beneath layer 413. One structure is “directly between” two other structures in a line if the two structures are located on opposite sides of the one structure in the line. For example, in FIG. 10, remaining portion 1003 is located directly between both the left and right sides of layer 413 in a line in the cut away side view of FIG. 10. Portion 1005 is not located directly between both the left and right sides of layer 413. A first structure is “directly lateral” to a second structure if the first structure and second structure are located in a line having a direction that is parallel with a generally planar major side of the wafer or substrate. For example, portion 1005 and layer 407 are directly lateral to each other. One structure is “directly laterally between” two other structures if the two structures are located on opposite sides of the one structure in a line that is parallel with a generally planar major side of the wafer or substrate. For example, in FIG. 10, portion 1003 is located directly laterally between both the left and right sides of layer 413. A surface is at a “higher elevation” than another surface, if that surface is located closer to the top of the active side of a wafer or die in a line having a direction that is perpendicular with the generally planar major side of the wafer or die. In the views of FIGS. 1-15, the active side of the wafer is the top side of the Figures. For example, layer 413 is at a higher elevation than layer 407. The term “immediately” when used to describe a relationship between two structures means that there is no intermediate structure between the two structures in the physical relationship. For example, in FIG. 10, layer 415 is immediately above layer 407. Layer 413 is not immediately above layer 407.

In one embodiment, a method includes forming a via dielectric layer over a wafer; forming an etch-stop layer over the via dielectric layer; forming an interconnect dielectric layer over the etch-stop layer; and forming a first opening in the via dielectric layer and the etch-stop layer and a second opening in the interconnect dielectric layer of an area greater than an area of the first opening. The first opening in the via dielectric layer extends through a bottom of the via dielectric layer, wherein the second opening is contiguous with the first opening, wherein a sidewall of the first opening in the via dielectric layer is defined by the sidewall of the first opening in the etch-stop layer. The method includes removing at least a top portion of the etch-stop layer immediately laterally adjacent to the first opening with an etch process to increase the width of the first opening in at least a top portion of the etch-stop layer, wherein portions of the etch-stop layer exposed by the second opening remain after the removing. The method includes after the removing, forming a barrier layer over the wafer including over surfaces of the first opening and surfaces of the second opening. The method includes forming conductive material over the barrier layer that fills the first opening and the second opening. The method includes planarizing the wafer to form a multi-level interconnect structure of material of the barrier layer and the conductive material in the first opening and the second opening.

In further embodiments, the method includes wherein multi-level interconnect structure includes a via portion located in the via dielectric layer and an interconnect portion located in the interconnect dielectric layer.

In further embodiments, the method includes wherein the removing removes material so as to provide for a more relaxed transition of the interconnect portion to the via portion at a location of the top of the first opening.

In further embodiments, the method includes wherein the removing at least a top portion of the etch-stop layer immediately adjacent to the first opening includes removing all of the etch-stop layer immediately adjacent to the first opening for at least a first distance from a location of the first opening in the via dielectric layer.

In further embodiments, the method includes wherein the removing at least a top portion of the etch-stop layer immediately adjacent to the first opening results in a sloped profile of an edge of the sidewall of the etch-stop layer of the first opening, wherein the top portion of the etch-stop layer is located laterally farther away from a location of the first opening in the via dielectric layer than a bottom portion of the etch-stop layer.

In further embodiments, the method includes wherein the removing at least a top portion of the etch-stop layer is performed with an etch process wherein a vertical component of the etch process is reduced with respect to a horizontal component of the etch process.

In further embodiments, the method includes wherein the removing at least a top portion of the etch-stop layer is performed with a plasma etch process that includes utilizing an angled etch of plasma ions with respect to a major surface of the wafer.

In further embodiments, the method includes forming a dielectric barrier layer, the via dielectric layer is formed over the dielectric barrier layer, wherein the forming the first opening includes forming the first opening in the dielectric barrier layer to expose a conductive structure, wherein the barrier layer contacts the conductive structure.

In further embodiments, the method includes wherein the etch-stop layer includes at least two sublayers wherein a first sublayer of the at least two sublayers is immediately below a second sublayer of the at least two sublayers, wherein after the removing, a sidewall of the second sublayer is located laterally farther away from a location of the first opening in the via dielectric layer than a sidewall of the first sublayer.

In further embodiments, the method includes wherein the removing includes etching the second sublayer to remove a portion of the second sublayer immediately laterally adjacent to the first opening with an etch process having etch chemistry that is etch-selective to material of the via dielectric layer and to material of the first sublayer to increase the width of the first opening in second sublayer; and wherein the removing includes etching the first sublayer to remove a portion of the first sublayer immediately adjacent to the first opening with an etch process having an etch chemistry that is etch-selective to material of the via dielectric layer to increase the width of the first opening in first sublayer.

In further embodiments, the method includes wherein the etch-stop layer includes a third sublayer of the at least two sublayers where a third sublayer of the at least two sublayers is immediately above the second sublayer, wherein after the removing, a sidewall of the third sublayer is located laterally farther away from the location of the first opening in the via dielectric layer than the sidewall of the second sublayer.

In further embodiments, the method includes wherein after the removing at least a top portion of the etch-stop layer immediately laterally adjacent to the first opening and prior to forming a barrier layer, removing a top portion of the sidewall of the first opening of the via dielectric layer by an etch process, wherein a bottom portion of the sidewall of the first opening of the via dielectric layer is not removed.

In further embodiments, the method includes after forming the first opening, filling the first opening with a filler of a material that is etch-selective with respect to a material of the via dielectric layer, wherein prior to removing a top portion of the sidewall of the via dielectric layer in the first opening, removing the filler in the first opening that is laterally adjacent to the top portion of the sidewall of the via dielectric layer in the first opening wherein a portion of the filler laterally adjacent to the bottom portion of the sidewall of the via dielectric layer in the first opening remains during the removing the top portion of the sidewall of the via dielectric layer in the first opening.

In further embodiments, the method includes wherein the filling the first opening with the filler is performed before forming the second opening.

In further embodiments, the method includes wherein forming the first opening includes forming the first opening in the interconnect dielectric material, wherein the filling the first opening with the filler includes filling the first opening in the interconnect dielectric layer with the filler.

In further embodiments, the method includes wherein the multi-level interconnect structure includes a via portion located in the via dielectric layer and an interconnect structure located in the interconnect dielectric layer; and the via portion electrically contacts a conductive structure located below the via dielectric layer.

In further embodiments, the method includes wherein the removing at least a top portion of the etch-stop layer immediately adjacent to the first opening includes performing a timed isotropic etch with an etch chemistry that is selective to the via dielectric layer.

In further embodiments, the method includes singulating the wafer into multiple semiconductor die where each semiconductor die includes at least one multi-level interconnect structure.

In further embodiments, the method includes wherein the etch-stop layer has a thickness in the range of 50-600 Angstroms.

In other embodiments, a method includes forming a via dielectric layer over a wafer; forming an etch-stop layer over the via dielectric layer; forming an interconnect dielectric layer over the etch-stop layer; forming a first opening in the via dielectric layer, the etch-stop layer, and the interconnect dielectric layer, wherein the first opening extends to a conductive structure at the bottom of the first opening; and filling the first opening in the via dielectric layer, the etch-stop layer, and the interconnect dielectric layer with a filler. The method further includes after filling the first opening, forming a second opening in the interconnect dielectric layer of an area greater than an area of the first opening, wherein forming the second opening includes removing the filler in the first opening of the interconnect dielectric layer and exposing a portion of the etch-stop layer. The method further includes after the forming the second opening, removing a portion of the etch-stop layer immediately laterally adjacent to the first opening to increase the width of the first opening in the etch-stop layer, wherein portions of the etch-stop layer exposed by the second opening remain after the removing the etch-stop layer. The method further includes removing the filler in the first opening of the via dielectric layer that is laterally adjacent to a top portion of a sidewall of the via dielectric layer in the first opening, wherein the filler laterally adjacent to a bottom portion of the sidewall of the via dielectric layer in the first opening remains during the removing the filler in the first opening of the via dielectric layer that is laterally adjacent to a top portion of a sidewall of the via dielectric layer in the first opening. The method further includes after the removing a portion of the etch-stop layer and after the removing the filler in the first opening of the via dielectric layer that is laterally adjacent to the top portion of the sidewall of the via dielectric layer, removing the top portion of the sidewall of the via dielectric layer in the first opening of by an etch process, wherein a bottom portion of sidewall of the via dielectric layer in the first opening is not removed by the etch process. The method further includes after the removing the top portion of the sidewall of the via dielectric layer in the first opening, removing a remaining portion of the filler in the first opening of the via dielectric layer. The method further includes after the removing the remaining portion, forming a barrier layer over the wafer including over surfaces of the first opening and surfaces of the second opening. The method further includes forming conductive material over the barrier layer that fills the first opening and the second opening; and planarizing the wafer to form a multi-level interconnect structure of material of the barrier layer and the conductive material in the first opening and the second opening.

Features specifically shown or described with respect to one embodiment set forth herein may be implemented in other embodiments set forth herein. The use of numerical terms (e.g., “first,” “second,” “third”) in the claims, (e.g., such as in “first opening” and “second opening”) are arbitrary designations to differentiate similarly named items (e.g., “openings”) and do not imply an order of formation.

While particular embodiments of the present invention have been shown and described, it will be recognized to those skilled in the art that, based upon the teachings herein, further changes and modifications may be made without departing from this invention and its broader aspects, and thus, the appended claims are to encompass within their scope all such changes and modifications as are within the true spirit and scope of this invention.

What is claimed is:

1. A method comprising:
forming a via dielectric layer over a wafer;
forming an etch-stop layer over the via dielectric layer;
forming an interconnect dielectric layer over the etch-stop layer;
forming a first opening in the via dielectric layer and the etch-stop layer and a second opening in the interconnect dielectric layer of an area greater than an area of the first opening, wherein the first opening in the via dielectric layer extends through a bottom of the via dielectric layer, wherein the second opening is contiguous with the first opening, wherein a sidewall of the first opening in the via dielectric layer is defined by the sidewall of the first opening in the etch-stop layer;
removing at least a top portion of the etch-stop layer immediately laterally adjacent to the first opening with an etch process to increase the width of the first opening in at least a top portion of the etch-stop layer, wherein portions of the etch-stop layer exposed by the second opening remain after the removing;
after the removing, forming a barrier layer over the wafer including over surfaces of the first opening and surfaces of the second opening;
forming conductive material over the barrier layer that fills the first opening and the second opening;
planarizing the wafer to form a multi-level interconnect structure of material of the barrier layer and the conductive material in the first opening and the second opening.

2. The method of claim 1 wherein multi-level interconnect structure includes a via portion located in the via dielectric layer and an interconnect portion located in the interconnect dielectric layer.

3. The method of claim 2 wherein the removing removes material so as to provide for a more relaxed transition of the interconnect portion to the via portion at a location of the top of the first opening.

4. The method of claim 1, wherein the removing at least a top portion of the etch-stop layer immediately adjacent to the first opening includes removing all of the etch-stop layer immediately adjacent to the first opening for at least a first distance from a location of the first opening in the via dielectric layer.

5. The method of claim 1, wherein the removing at least a top portion of the etch-stop layer immediately adjacent to the first opening results in a sloped profile of an edge of the sidewall of the etch-stop layer of the first opening, wherein the top portion of the etch-stop layer is located laterally farther away from a location of the first opening in the via dielectric layer than a bottom portion of the etch-stop layer.

6. The method of claim 5 wherein the removing at least a top portion of the etch-stop layer is performed with an etch process wherein a vertical component of the etch process is reduced with respect to a horizontal component of the etch process.

7. The method of claim 5 wherein the removing at least a top portion of the etch-stop layer is performed with a plasma etch process that includes utilizing an angled etch of plasma ions with respect to a major surface of the wafer.

8. The method of claim 1 further comprising forming a dielectric barrier layer, the via dielectric layer is formed over the dielectric barrier layer, wherein the forming the first opening includes forming the first opening in the dielectric barrier layer to expose a conductive structure, wherein the barrier layer contacts the conductive structure.

9. The method of claim 1 wherein the etch-stop layer includes at least two sublayers wherein a first sublayer of the at least two sublayers is immediately below a second sublayer of the at least two sublayers, wherein after the removing, a sidewall of the second sublayer is located laterally farther away from a location of the first opening in the via dielectric layer than a sidewall of the first sublayer.

10. The method of claim 9 wherein:
the removing includes etching the second sublayer to remove a portion of the second sublayer immediately laterally adjacent to the first opening with an etch process having etch chemistry that is etch-selective to material of the via dielectric layer and to material of the first sublayer to increase the width of the first opening in second sublayer;
the removing includes etching the first sublayer to remove a portion of the first sublayer immediately adjacent to the first opening with an etch process having an etch chemistry that is etch-selective to material of the via dielectric layer to increase the width of the first opening in first sublayer.

11. The method of claim 9 wherein the etch-stop layer includes a third sublayer of the at least two sublayers where a third sublayer of the at least two sublayers is immediately above the second sublayer, wherein after the removing, a sidewall of the third sublayer is located laterally farther away from the location of the first opening in the via dielectric layer than the sidewall of the second sublayer.

12. The method of claim 1 wherein after the removing at least a top portion of the etch-stop layer immediately laterally adjacent to the first opening and prior to forming a barrier layer, removing a top portion of the sidewall of the first opening of the via dielectric layer by an etch process, wherein a bottom portion of the sidewall of the first opening of the via dielectric layer is not removed.

13. The method of claim 12 further comprising, after forming the first opening, filling the first opening with a filler of a material that is etch-selective with respect to a material of the via dielectric layer, wherein prior to removing a top portion of the sidewall of the via dielectric layer in the first opening, removing the filler in the first opening that is laterally adjacent to the top portion of the sidewall of the via dielectric layer in the first opening wherein a portion of the filler laterally adjacent to the bottom portion of the sidewall of the via dielectric layer in the first opening remains during the removing the top portion of the sidewall of the via dielectric layer in the first opening.

14. The method of claim 13, wherein the filling the first opening with the filler is performed before forming the second opening.

15. The method of claim 14 wherein forming the first opening includes forming the first opening in the interconnect dielectric material, wherein the filling the first opening with the filler includes filling the first opening in the interconnect dielectric layer with the filler.

16. The method of claim 1 wherein:
the multi-level interconnect structure includes a via portion located in the via dielectric layer and an interconnect structure located in the interconnect dielectric layer;
the via portion electrically contacts a conductive structure located below the via dielectric layer.

17. The method of claim 1 wherein the removing at least a top portion of the etch-stop layer immediately adjacent to the first opening includes performing a timed isotropic etch with an etch chemistry that is selective to the via dielectric layer.

18. The method of claim 1 further comprising singulating the wafer into multiple semiconductor die where each semiconductor die includes at least one multi-level interconnect structure formed by the method of claim 1.

19. The method of claim 1 wherein the etch-stop layer has a thickness in the range of 50-600. Angstroms.

20. A method comprising:
forming a via dielectric layer over a wafer;
forming an etch-stop layer over the via dielectric layer;
forming an interconnect dielectric layer over the etch-stop layer;
forming a first opening in the via dielectric layer, the etch-stop layer, and the interconnect dielectric layer, wherein the first opening extends to a conductive structure at the bottom of the first opening;
filling the first opening in the via dielectric layer, the etch-stop layer, and the interconnect dielectric layer with a filler;
after filling the first opening, forming a second opening in the interconnect dielectric layer of an area greater than an area of the first opening, wherein forming the second opening includes removing the filler in the first opening of the interconnect dielectric layer and exposing a portion of the etch-stop layer;
after the forming the second opening, removing a portion of the etch-stop layer immediately laterally adjacent to the first opening to increase the width of the first opening in the etch-stop layer, wherein portions of the etch-stop layer exposed by the second opening remain after the removing the etch-stop layer;
removing the filler in the first opening of the via dielectric layer that is laterally adjacent to a top portion of a sidewall of the via dielectric layer in the first opening, wherein the filler laterally adjacent to a bottom portion of the sidewall of the via dielectric layer in the first opening remains during the removing the filler in the first opening of the via dielectric layer that is laterally adjacent to a top portion of a sidewall of the via dielectric layer in the first opening;
after the removing a portion of the etch-stop layer and after the removing the filler in the first opening of the via dielectric layer that is laterally adjacent to the top portion of the sidewall of the via dielectric layer, removing the top portion of the sidewall of the via dielectric layer in the first opening of by an etch process, wherein a bottom portion of sidewall of the via dielectric layer in the first opening is not removed by the etch process;
after the removing the top portion of the sidewall of the via dielectric layer in the first opening, removing a remaining portion of the filler in the first opening of the via dielectric layer;
after the removing the remaining portion, forming a barrier layer over the wafer including over surfaces of the first opening and surfaces of the second opening;
forming conductive material over the barrier layer that fills the first opening and the second opening;
planarizing the wafer to form a multi-level interconnect structure of material of the barrier layer and the conductive material in the first opening and the second opening.
